(19) United States
(12) Patent Application Publication
(10) Pub. No.: US 2025/0098179 A1
(43) Pub. Date: Mar. 20, 2025

(54) MEMORY LAYERS AT OPPOSING SIDES OF A COMPLEMENTARY METAL-OXIDE SEMICONDUCTOR LAYER

(71) Applicants: Abhishek A. Sharma, Portland, OR (US); Van H. Le, Beaverton, OR (US); Fatih Hamzaoglu, Portland, OR (US); Juan G. Alzate-Vinasco, Tigard, OR (US); Nikhil Jasvant Mehta, Portland, OR (US); Vinaykumar Hadagali, Portland, OR (US); Yu-Wen Huang, Beaverton, OR (US); Honore Djieutedjeu, Rio Rancho, NM (US); Tahir Ghani, Portland, OR (US); Timothy Jen, Portland, OR (US); Shailesh Kumar Madisetti, Hillsboro, OR (US); Jisoo Kim, Portland, OR (US); Wilfred Gomes, Portland, OR (US); Kamal Baloch, Portland, OR (US); Vamsi Evani, Hillsboro, OR (US); Christopher Wiegand, Portland, OR (US); James Pellegren, Portland, OR (US); Sagar Suthram, Portland, OR (US); Christopher M. Pelto, Beaverton, OR (US); Gwang Soo Kim, Portland, OR (US); Babita Dhayal, Aloha, OR (US); Prashant Majhi, San Jose, CA (US); Anand Iyer, Saratoga, CA (US); Anand S. Murthy, Portland, OR (US); Pushkar Sharad Ranade, San Jose, CA (US); Pooya Tadayon, Portland, OR (US); Nitin A. Deshpande, Chandler, AZ (US)

(72) Inventors: Abhishek A. Sharma, Portland, OR (US); Van H. Le, Beaverton, OR (US); Fatih Hamzaoglu, Portland, OR (US); Juan G. Alzate-Vinasco, Tigard, OR (US); Nikhil Jasvant Mehta, Portland, OR (US); Vinaykumar Hadagali, Portland, OR (US); Yu-Wen Huang, Beaverton, OR (US); Honore Djieutedjeu, Rio Rancho, NM (US); Tahir Ghani, Portland, OR (US); Timothy Jen, Portland, OR (US); Shailesh Kumar Madisetti, Hillsboro, OR (US); Jisoo Kim, Portland, OR (US); Wilfred Gomes, Portland, OR (US); Kamal Baloch, Portland, OR (US); Vamsi Evani, Hillsboro, OR (US); Christopher Wiegand, Portland, OR (US); James Pellegren, Portland, OR (US); Sagar Suthram, Portland, OR (US); Christopher M. Pelto, Beaverton, OR (US); Gwang Soo Kim, Portland, OR (US); Babita Dhayal, Aloha, OR (US); Prashant Majhi, San Jose, CA (US); Anand Iyer, Saratoga, CA (US); Anand S. Murthy, Portland, OR (US); Pushkar Sharad Ranade, San Jose, CA (US); Pooya Tadayon, Portland, OR (US); Nitin A. Deshpande, Chandler, AZ (US)

(21) Appl. No.: 18/467,984

(22) Filed: Sep. 15, 2023

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1436; H01L 2924/1437

(57) ABSTRACT

An IC device may include a CMOS layer and memory layers at the frontside and backside of the CMOS layer. The CMOS layer may include one or more logic circuits with MOSFET transistors. The CMOS layer may also include memory cells, e.g., SRAM cells. A memory layer may include one or more memory arrays. A memory array may include memory cells (e.g., DRAM cells), bit lines, and word lines. A logic circuit in the CMOS layer may control access to the memory cells. A memory layer may be bonded with the CMOS layer through a bonding layer that includes conductive structures coupled to a logic circuit in the CMOS layer or to bit lines or word lines in the memory layer. An additional conductive structure may be at the backside of a MOSFET transistor in the CMOS layer and coupled to a conductive structure in the bonding layer.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. The FEOL stage may include a complementary metal-oxide-semiconductor (CMOS) process, in which metal-oxide-semiconductor field-effect transistors (MOSFETs) (such as symmetrical pairs of P-type and N-type MOSFETs) can be fabricated. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a perspective view of an IC device with memory layers at both frontside and backside of a CMOS layer, according to some embodiments of the disclosure.

FIG. 1B illustrates an example memory layer, according to some embodiments of the disclosure.

FIG. 2 is a cross-sectional view of an IC device with memory layers at both frontside and backside of a CMOS layer, according to some embodiments of the disclosure.

FIG. 3 illustrates an IC device including a stack of wafers, according to some embodiments of the disclosure.

FIG. 4 is an electric circuit diagram of an example dynamic random-access memory (DRAM) array, according to some embodiments of the present disclosure.

FIG. 5A is an electric circuit diagram of an example static random-access memory (SRAM) cell, according to some embodiments of the present disclosure.

FIG. 5B provides a top-down plan view of an example implementation of the SRAM cell, according to some embodiments of the present disclosure.

FIG. 6 illustrates an IC device with memory layers sharing word line drivers and sense amplifiers in a CMOS layer that is boned to the memory layers through bonding layers, according to some embodiments of the present disclosure.

FIG. 7 illustrates another IC device with memory layers sharing word line drivers and sense amplifiers in a CMOS layer that is boned to the memory layers through bonding layers, according to some embodiments of the present disclosure.

FIGS. 8A and 8B are top views of a wafer and dies that can facilitate memory layers at opposing sides of a CMOS layer, according to some embodiments of the disclosure.

FIG. 9 is a side, cross-sectional view of an example IC package that may include memory layers at opposing sides of a CMOS layer, according to some embodiments of the disclosure.

FIG. 10 is a cross-sectional side view of an IC device assembly that may include components having memory layers at opposing sides of a CMOS layer, according to some embodiments of the disclosure.

FIG. 11 is a block diagram of an example computing device that may include one or more components with memory layers at opposing sides of a CMOS layer, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to SRAM. Other embodiments of the present disclosure may refer to DRAM. However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays.

A memory cell is a fundamental building block of computer memory devices used to store and retrieve data. It is a small unit of storage that can hold a single bit of information, which can be either a 0 or a 1. Memory cells are organized in a grid-like structure to form memory arrays. A memory cell usually includes a memory element, which stores information, and an access transistor, which is coupled to the memory element and controls access to the memory element. A memory device also includes bit lines and word lines coupled to memory cells. A bit line can couple the memory cells in the memory array to the memory control circuitry. A bit line can be used for reading and writing data. A word line can be used to control the access to a specific row of memory cells in the memory array. When the word line is activated, it enables the data stored in the selected row to be read or modified.

Currently available memory devices usually have logic circuits in memory layers. A memory layer may be a memory die or memory wafer. Such logic circuits may be peripheral circuits, such as sense amplifiers, decoders timers, and so on. Fabrication of such memory layers can require CMOS processes. However, CMOS processes are not always cost efficient. The cost of manufacturing such memory layers can be higher than desired.

Embodiments of the present disclosure may improve on at least some of the challenges and issues described above by providing memory layers arranged at frontside and backside of CMOS layers. In an example, a CMOS layer may include logic circuits or devices that are fabricated using one or more CMOS processes. Memory layers may be fabricated using non-CMO processes, such as BEOL process. The memory layers may be placed at the frontside and the backside of the CMOS layer. The memory layers may be boned to the CMOS layer. Also, the memory layer may be electrically coupled to the CMOS layer so that logic circuits or devices in the CMOS layer may control operations of the memory layers. The logic functions in the CMOS layer can facilitate computation in memory. The cost of fabricating the memory layers can be reduced as usage of CMOS fabrication is avoided.

In various embodiments of the present disclosure, an IC device (which may also be referred to as an IC assembly) may include a CMOS layer that is at least partially fabricated using a CMOS process. The CMOS layer may include transistors (e.g., MOSFETs) fabricated using the CMOS process. The transistors may be used to form logic circuits. Additionally or alternatively, the transistor may be used in memory cells, e.g., SRAM cells. Memory layers may be attached to the frontside and backside of the CMOS layer. For instance, one or more memory layers may be arranged at each of the frontside and backside. A memory layer may include one or more memory arrays. A memory array may include memory cells coupled to bit lines and word lines. A memory cell in a memory layer may be a DRAM cell, SRAM cell, magnetoresistive random-access memory (MRAM) cell, ferroelectric memory cell, and so on. A logic circuit in the CMOS layer may control access to memory cells in the memory layers. A memory layer may be bonded with the CMOS layer through a bonding layer. The bonding layer may provide a hybrid bonding interface (HBI). In an example, the bonding layer may include a bonding material that facilitates adhesion between the memory layer and the CMOS layer. The bonding layer may also include conductive structures that couple one or more logic circuits in the CMOS layer to one or more memory arrays in the memory layer. In some embodiments, an additional conductive structure may be used for connecting the memory layer to the CMOS layer. The additional conductive structure may be connected to a MOSFET transistor (e.g., from the backside of the MOSFET) in the CMOS layer and coupled to a conductive structure in the bonding layer.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

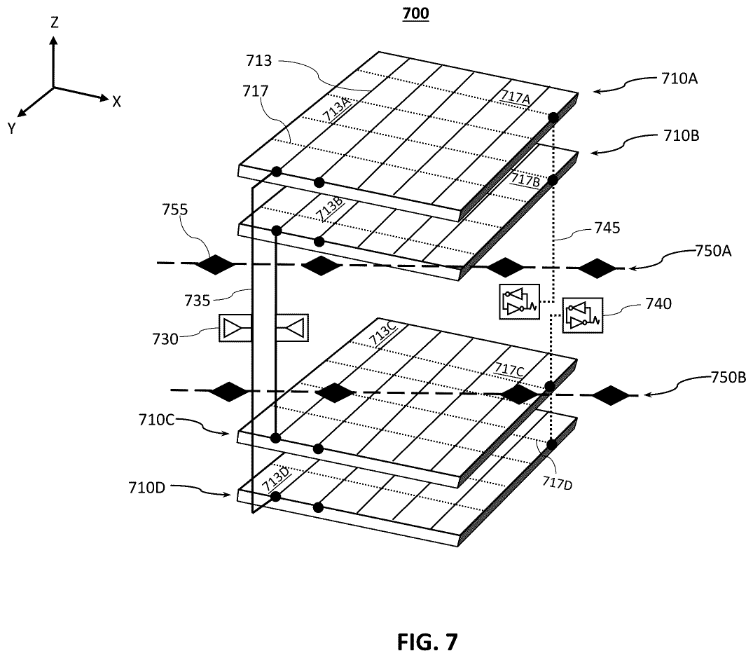

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of memory layers at opposing sides of a CMOS layer as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment.

Various additional operations may be performed, and/or described operations may be omitted in additional embodiments.

Various memory layers at opposing sides of a CMOS layer as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

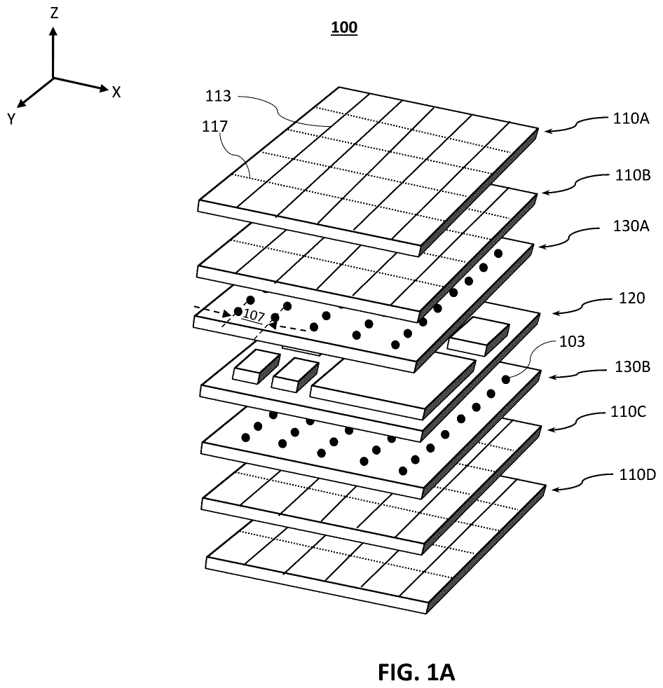

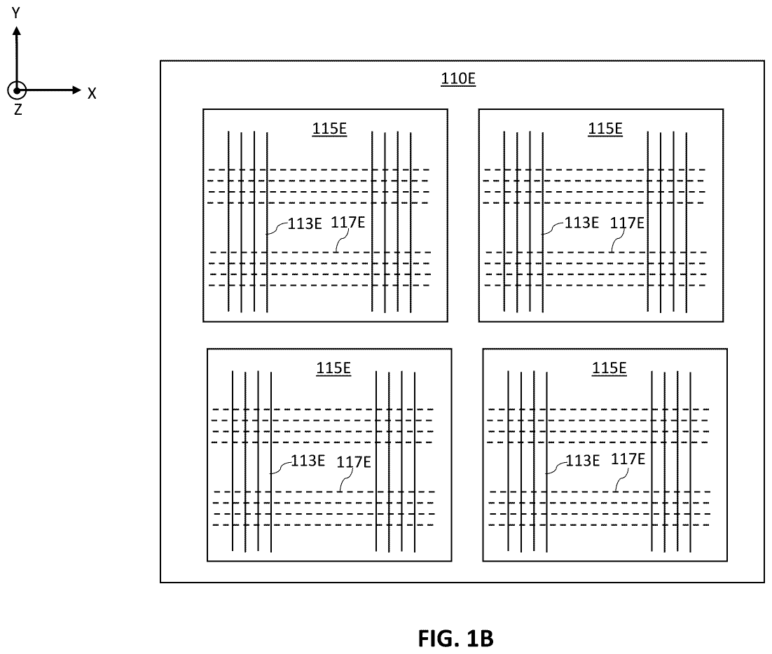

FIG. 1A is a perspective view of an IC device 100 with memory layers 110A-110D (collectively referred to as “memory layers 110” or “memory layer 110”) at both frontside and backside of a CMOS layer 120, according to some embodiments of the disclosure. The IC device 100 also includes bonding layers 130A and 130B. In other embodiments, the IC device 100 may include fewer, more, or different components. The IC device 100 may also be referred to as an IC assembly. Even though the memory layers 110 are on the top and bottom of the CMOS layer 120, one or more of the memory layers 120 or one or more other memory layers may be at the left or right side of the CMOS layer 120.

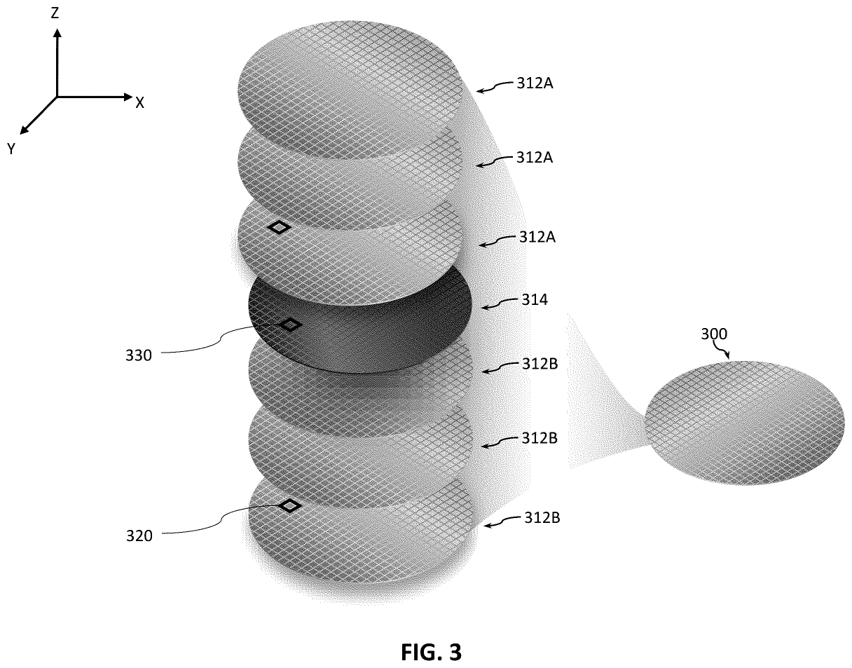

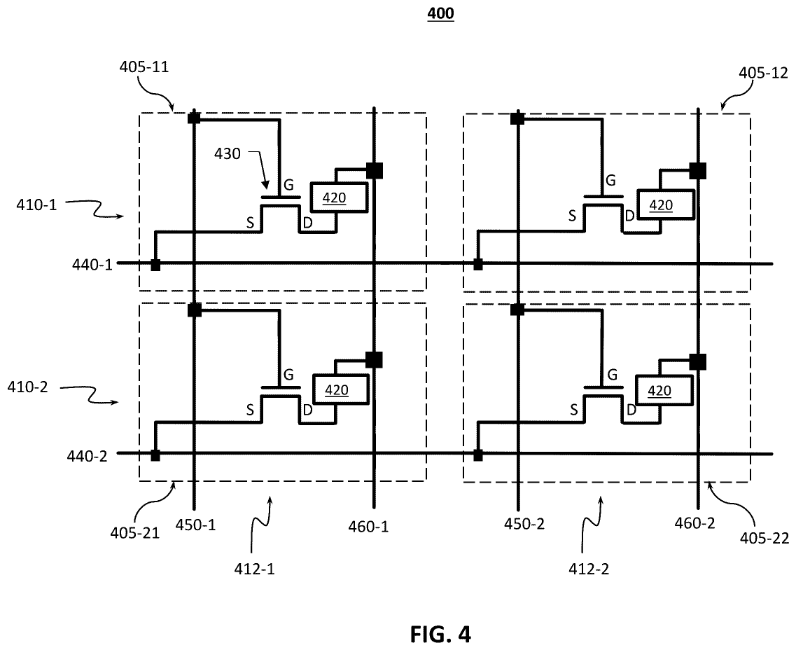

Each memory layer 110 may be a memory die or memory wafer. In some embodiments, each memory layer 110 includes one or more memory arrays. A memory array may include memory cells arranged in rows and columns, one or more bit lines, and one or more word lines. An example memory cell may include a memory element and one or more access transistors. A row memory cells may be coupled to a common word line. A column of memory cells may be coupled to a common bit line. A memory cell may be activated or accessed (e.g., for data read or write operations) using the corresponding word line and bit line. In some embodiments, each memory layer 110 may be a DRAM device that includes DRAM arrays. More details regarding memory layers are provided below in conjunction with FIG. 3. More details regarding DRAM array are provided below in conjunction with FIG. 4.

As shown in FIG. 1A, the memory layers 110A and 110B are at the frontside of the CMOS layer 120, and the memory layers 110C and 110D are at the backside of the CMOS layer 120. In other embodiments, the IC device 100 may include a different number of memory layers 110 at the frontside or backside of the CMOS layer 120. The memory layers 110 may be fabricated through a different process from the CMOS layer 120. For instance, the CMOS layer 120 may be fabricated using one or more CMOS processes, in which MOSFETs may be formed. The CMOS process(es) may be part of a FEOL process. The MOSFETs may be used in logic circuits in the CMOS layer 120 for controlling operations of the memory cells in memory layer 110. In contrast, transistors of memory cells in the memory layers 110 may be fabricated through a BEOL process, which does not require CMOS fabrication. Transistors of memory cells in the memory layers 110 may be referred to as backend transistors.

In some embodiments, the CMOS layer 120 may include P-type transistors and N-type transistors. A memory layer 110 may include either P-type transistors or N-type transistors. A semiconductor structure of a transistor in a memory layer 110 or the CMOS layer 120 may be formed through deposition of one or more semiconductor material. In some embodiments, a semiconductor structure of a transistor in a memory layer 110 or the CMOS layer 120 may be a single crystal epitaxial structure for low temperatures.

In some embodiments, the memory layers 110 may be fabricated separately from each other or from the CMOS layer 120. A memory layer 110 may be coupled to the CMOS layer 120 after the CMOS layer 120 is formed. In an example, the memory layer 110B or memory layer 110C may be attached to the CMOS layer 120 (e.g., using the bonding layer 130A or 130B) after the CMOS layer 120 is formed. After the attachment, the memory layer 110A may be placed over the memory layer 110B, and the memory layer 110D may be placed over the memory layer 110C. In another example, the memory layers 110A and 110B may be assembled into one memory layer set and after that, the memory layer set is attached to the frontside of the CMOS layer 120. Similarly, the memory layers 110C and 110D may be assembled into one memory layer set and after that, the memory layer set is attached to the backside of the CMOS layer 120. One or more additional memory layers 110 may be added to the frontside or backside of the CMOS layer 120. Given the presence of the CMOS layer 120 between the memory layers 110, the IC device 100 is capable of “computation in memory.” The process for fabricating the memory layer 110 can cost less than the CMOS process and therefore, the overall cost for fabricating the IC device 100 can be reduced.

Each memory layer 110 may include one or more semiconductor structures, which may facilitate formation of transistors in the memory layer 110. A semiconductor structure provides semiconductor regions (e.g., channel region, source region, drain region, etc.) of backend transistors in the memory layer 110. For the purpose of simplicity and illustration, other components (e.g., gate, source electrode, drain electrode, etc.) of backend transistors are not shown in FIG. 1A. In some embodiments, a semiconductor structure may include a channel material. The channel material may be composed of semiconductor material systems including, for example, N-type or P-type materials systems. In some embodiments, the channel material 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 104 may include a combination of semiconductor materials where one semiconductor material may be used for a channel portion of a transistor and another material, sometimes referred to as a “blocking material,” may be used between the channel portion and the support structure over which the transistor is provided. In some embodiments, the channel material may include a monocrystalline semiconductor, such as silicon (Si) or germanium (Ge). In some embodiments, the channel material may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistors implemented in the memory layers 110 are N-type metal-oxide-semiconductor (NMOS) transistors), the channel portions of the channel material may advantageously include a III-V material having a high electron mobility, such as, but not limited to InGaAs, InP, InSb, and InAs. For some such embodiments, the channel portions of the channel material may be a ternary III-V alloy, such as InGaAs, GaAsSb, InAsP, or InPSb. For some InxGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portions of the channel material may be an intrinsic III-V material, i.e., a III-V semiconductor material not intentionally doped with any electrically active impurity. In alternate embodiments, a nominal impurity dopant level may be present within the channel portions of the channel material, for example to further fine-tune a threshold voltage Vt, or to provide HALO pocket implants, etc. Even for impurity-doped embodiments however, impurity dopant level within the channel portions of the channel material may be relatively low, for example below 10¹⁵ dopant atoms per cubic centimeter (cm⁻³), and advantageously below 10¹³ cm⁻³.

For some example P-type transistor embodiments (i.e., for the embodiments where the transistors implemented in the memory layers 110 are P-type metal-oxide-semiconductor (PMOS) transistors), the channel portions of the channel material may advantageously be a group IV material having a high hole mobility, such as, but not limited to Ge or a Ge-rich SiGe alloy. For some example embodiments, the channel portions of the channel material may have a Ge content between 0.6 and 0.9, and advantageously may be at least 0.7. In some embodiments with highest mobility, the channel portions of the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portions of the channel material is relatively low, for example below 10¹⁵ cm⁻³, and advantageously below 10¹³ cm⁻³.

In some embodiments, the transistors implemented in the memory layers 110 may be thin film transistors (TFTs). A TFT is a special kind of a field-effect transistor made by depositing a thin film of an active semiconductor material, as well as a dielectric layer and metallic contacts, over a supporting layer that may be a non-conducting layer. At least a portion of the active semiconductor material forms a channel of the TFT. If transistors implemented in the memory layers 110 are TFTs, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, for TFTs, the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material may have a thickness between about 5 and 75 nanometers, including all values and ranges therein. In some embodiments, a thin film channel material may be deposited at relatively low temperatures, which allows depositing the channel material within the thermal budgets imposed on backend fabrication to avoid damaging other components, e.g., frontend components such as the logic devices of the CMOS layer 120.

The CMOS layer 120 may be a logic layer, such as a logic die or logic wafer, which may also be referred to as a compute die/wafer or compute logic die/wafer. The CMOS layer 120 controls the memory layers 110. The CMOS layer 120 may include one or more logic circuits that control operations of the memory layers 110. A logic circuit may be a peripheral circuit. A logic circuit may include transistors fabricated through a CMOS process. For instance, the transistors can be used to form sense amplifiers, row decoders, column decoders, word line drivers, timers, multipliers, CMOS logic, SRAM cells, power delivery network, signal delivery network, or other types of devices or circuits in the CMOS layer 120.

A sense amplifier may amplify and restore weak signals, e.g., to a more robust and usable level. In some embodiments, for reading data from the memory layers 110, the sense amplifier may detect and amplify the small voltage difference between the stored data states, typically representing binary values of 0 and 1. By amplifying this voltage difference, the sense amplifier can enable accurate and reliable data retrieval. In some embodiments (e.g., embodiments having high speed data transmission), the sense amplifier may amplify weak signals to avoid signal degradation and noise during signal propagation so that the signals can be more immune to noise, which can enable more accurate data recovery. The sense amplifier may be a latch-based sense amplifier, differential sense amplifier, dynamic sense amplifier, or other types of sense amplifiers.

A row decoder may select which rows of memory cells in memory arrays to be accessed based on memory addresses. In some embodiments, the row decoder may receive an input signal with information indicating a memory address. The row decoder may decode the memory address and select the row(s) corresponding to the memory address. The row decoder may further activate the row(s), e.g., by selecting and enabling the word line of each selected row. After a row is selected and activated, the logic circuit can perform read or write operations on the memory cells in the row. In some embodiments, the row decoder may further include a row driver for each word line to drive a signal down the word line. The row decoder may include a digital circuit that can be used to decode memory addresses, select rows of memory cells, or activate word lines. The digital circuit may include one or more logic gates. In some embodiments, the row decoder may include one or more inverters to drive the word line.

A column decoder selects which column(s) of memory cells in memory arrays to be accessed based on memory addresses received from a logic circuit. The column decoder may decode a column address and activate the corresponding column of memory cells. The column decoder may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder may depend on the size of the memory array. For example, in a memory system with 8 columns, the memory column decoder would have 3 address inputs (since 2\hat{ }3=8) and 8 output signals, each corresponding to a specific column. When a particular column address is provided, the column decoder may activate the corresponding output signal, enabling the memory cells in that column for read or write operations. The row decoder and column decoder can facilitate efficient and accurate access to specific rows of memory cells within the memory array and can support retrieval and storage of data in computer systems.

As described below, the memory layers 110 may be bonded with the CMOS layer 120 through the bonding layers 130A and 130B (collectively referred to as “bonding layers 130” or “bonding layer 130”). Each bonding layer 130 includes a plurality of conductive structures 103 for coupling components in the corresponding memory layer 110 to the CMOS layer 120. For instance, a conductive structure 103 may have an end connected to one or more components (e.g., via, interconnect, transistor, etc.) in the memory layer 110 and another end connected to one or more components (e.g., via, interconnect, transistor, etc.) in the CMOS layer 120. The conductive structures 103 may facilitate power delivery from the CMOS layer to the memory layers 110 and signal delivery between the CMOS layer and the memory layers 110. A conductive structure 103 may be, or may include, a via. The via may be a through silicon via (TSV) in some embodiments. The conductive structures 103 may have a pitch 107. The pitch 107 is a center-to-center distance of two adjacent conductive structures 103. In some embodiments, the pitch 107 is in a range from approximately 150 nm to approximately 15 micrometers. Even though the pitch 107 is a distance along the X axis in FIG. 1A, the conductive structures 103 may have the same or similar pitch along the Y axis.

In some embodiments, the bonding layer 130A provides a HBI between the memory layer 110B and the CMOS layer 120, and the bonding layer 130B provides a HBI between the memory layer 110C and the CMOS layer 120. In some embodiments, hybrid bonding may be performed either on a wafer-level, e.g., wafers may be hybrid bonded before they are separated into dies. In other embodiments, hybrid bonding may be performed on a die-level, e.g., dies may be hybrid bonded after the corresponding wafers have been separated into dies.

In general, hybrid manufacturing is described herein with reference to a first IC structure (e.g., a memory layer 110) and a second IC structure (e.g., the CMOS layer 120) bonded to one another using a bonding material. The first and second IC structures may be fabricated by different manufacturers, using different materials, or different manufacturing techniques. For each IC structure, the terms “bottom face” or “backside” of the structure may refer to the back of the IC structure, e.g., bottom of the support structure of a given IC structure, while the terms “top face” or “frontside” of the structure may refer to the opposing other face. When the top face of the first IC structure is bonded to the top face of the second IC structure, the structures are described as bonded “face-to-face” (f2f). When the top face of the first IC structure is bonded to the bottom face of the second IC structure or the bottom face of the first IC structure is bonded to the top face of the second IC structure, the structures are described as bonded “face-to-back” (f2b). When the bottom face of the first IC structure is bonded to the bottom face of the second IC structure, the structures are described as bonded “back-to-back” (b2b).

In some embodiments, bonding of the faces of the first and second IC structures may be performing using insulator-insulator bonding, e.g., as oxide-oxide bonding, where an insulating material of the first IC structure is bonded to an insulating material of the second IC structure. In some embodiments, a bonding material may be present in between the faces of the first and second IC structures that are bonded together. The bonding material may be applied to the one or both faces of the first and second IC structures that should be bonded and then the first and second IC structures are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the first and second IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using an etch-stop material at the interface (i.e., the interface between the first and second IC structures) that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the first and second IC structures together. In addition, an etch-stop material at the interface between the first and second IC structures that includes include silicon, nitrogen, and carbon, where the atomic percentage of any of these materials may be at least 1%, may be advantageous in terms of improving etch-selectivity of this material with respect to etch-stop materials that may be used in different of the first and second IC structures.

In some embodiments, no bonding material may be used, but there will still be a bonding interface resulting from the bonding of the first and second IC structures to one another. Such a bonding interface may be recognizable as a seam or a thin layer in the microelectronic assembly, using, e.g., selective area diffraction (SED), even when the specific materials of the insulators of the first and second IC structures that are bonded together may be the same, in which case the bonding interface would still be noticeable as a seam or a thin layer in what otherwise appears as a bulk insulator (e.g., bulk oxide) layer.

In some embodiments, one or more of conductive structures (e.g., power via, signal via, etc.) may be provided after the memory layers 110 and the CMOS layer 120 have been hybrid bonded. A via may extend from one surface of a CMOS layer 120 towards the opposing surface of the CMOS layer 120, and may extend through the corresponding bonding layer 130, to provide signal and/or power to various IC components (e.g., transistors) in the memory layer 110. A conductive structure may further extend through the memory layer 110 and into the next one or more memory layers 110 to facilitate signal or power delivery for the next memory layer(s) 110.

FIG. 1B illustrates an example memory layer 110E, according to some embodiments of the disclosure. The memory layer 110E may be an example of the memory layers 110 in FIG. 1A. The memory layer 110E includes a plurality of memory arrays 115E. For the purpose of illustration, the memory array 110E in FIG. 1B includes four memory arrays 115E. In other embodiments, the memory layer 110E may include a different number of memory arrays. A memory array may be a DRAM array.

Each memory array 115E includes word lines 113E (individually referred to as “word line”), bit lines 117E (individually referred to as “bit line 117E”), and a plurality of memory cells connected to the word lines 113E and bit lines 117E. The word lines 113E may be examples of the word lines 113 in FIG. 1A. The bit lines 117E may be examples of the bit lines 117 in FIG. 1A. For the purpose of illustration, the memory cells are not shown in FIG. 1B. A memory cell may be coupled to a word line 113E and a bit line 117E. In some embodiments, the memory cells in the memory array 115E are arranged in rows and columns. A row of memory cells may be coupled to a word line 113E. The word line 113E may be used to access the memory cells in the row. For instance, when the word line 113E is activated, the row of memory cells may be selected and accessed for data read operations or data write operations. The word lines 113E may also be referred to as row select lines. A column of memory cells may be connected to a bit line 117E. The bit line 117E may be used to access the memory cells in the column. For instance, when the bit line 117E is activated, the column of memory cells may be selected and accessed for data read operations or data write operations. In some embodiments, each column of memory cells is connected to two bit lines 117E: a first bit line 117E and a second bit line 117E that is the inverse of the first bit line 117E. A bit of data may be stored in a column of memory cells.

In some embodiments, a memory cell may include one or more transistors. A transistor in a memory cell may receive power from the CMOS layer 120. For instance, an electrode over the source or drain region of the transistor may be coupled to a power via and the power via may be coupled to a power interconnect in the CMOS layer 120. Additionally or alternatively, the transistor may receive a signal from the CMOS layer 120. For instance, a gate electrode in the transistor may be coupled to a signal via, and the signal via may be coupled to a signal interconnect in the CMOS layer 120.

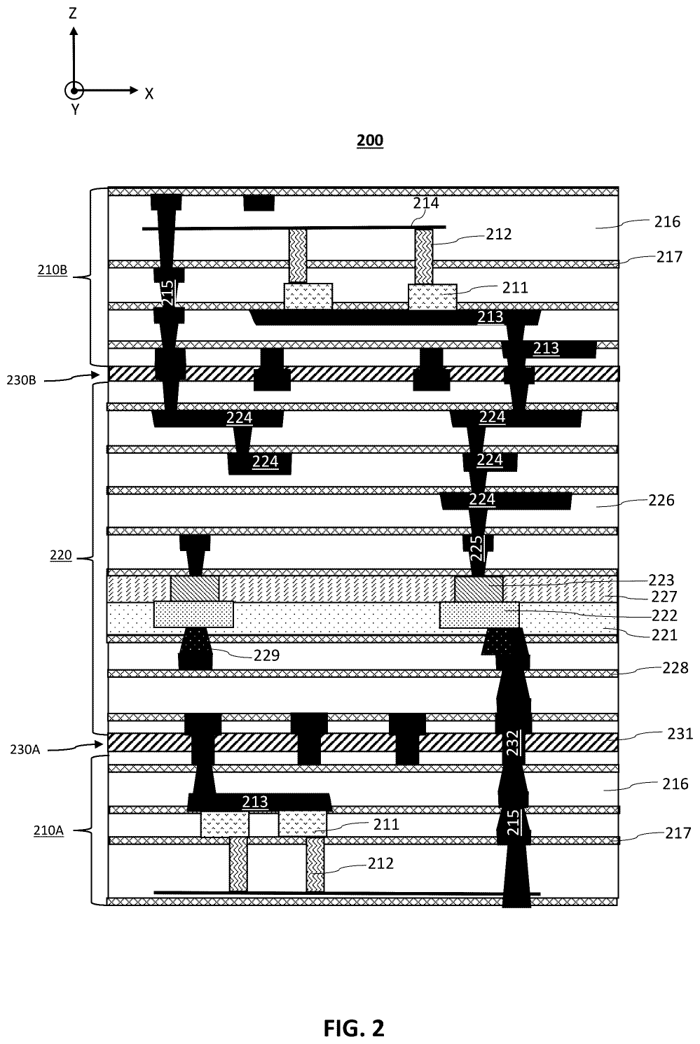

FIG. 2 is a cross-sectional view of an IC device 200 with memory layers 210A and 210B at both frontside and backside of a CMOS layer 220, according to some embodiments of the disclosure. The IC device 200 is an example of the IC device 100 in FIG. 1A. The memory layers 210A and 210B are collectively referred to as “memory layers 210” or “memory layer 210.” The memory layers 210 may be examples of the memory layers 110 in FIG. 1A. As shown in FIG. 2, in addition to the memory layers 210, the IC device 200 also includes bonding layers 230A and 230B, collectively referred to as “bonding layers 230” or “bonding layer 230.” The CMOS layer 220 may be an example of the CMOS layer 120 in FIG. 1A. The bonding layers 230 may be examples of the bonding layers 130 in FIG. 1A.

Each memory layer includes two transistors 211 (individually referred to as “transistor 211”), two capacitors 212 (individually referred to as “transistor 212”), interconnects 213 and 214, and various vias 215 (individually referred to as “via 215”), an electrical insulator 216, and various dielectric layers 217 (individually referred to as “dielectric layer 217”). In other embodiments, a memory layer 210 may include fewer, more, or different components. The transistors 211 and capacitors 212 may be formed in a BEOL process. The transistors 211 are coupled to the capacitors 212. In some embodiments, each capacitor 212 is coupled to an electrode of the corresponding transistor 212. The electrode may be a source electrode that is over a source region of the transistor 211 or a drain electrode that is over a drain region of the transistor 211. In some embodiments, each transistor 211 may be an access transistor of a memory cell, and the capacitor 212, which is coupled to the transistor 211, may be a memory element of the memory cell. The two transistors 211 and two capacitors 212 may be in two memory cells. In other embodiments, each memory layer 210 may include a different number of memory cells.

The interconnects 213 and 214 and vias 215 are conductive structures in the memory layers 210 and can facilitate delivery of power or signals to the memory cells. Each conductive structure may include one or more metals, such as tungsten (W), molybdenum (Mo), ruthenium (Ru), copper (Cu), other metals, or some combination thereof. In some embodiments, the interconnects 213 and 214 and vias 215 are coupled to the transistor 211 and capacitors 212. In FIG. 2, the interconnect 213 is connected to a via 215, and the interconnect 214 may be connected to terminals of the capacitors 212. Even though not shown in FIG. 2, a via 215 may be connected to another via, an electrode (e.g., gate electrode, source electrode, or drain electrode) of a transistor 211, or a terminal of a capacitor 212.

The electrical insulator 216 may include a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc. The dielectric layers 217 may also be insulative. In some embodiments, a dielectric layer 217 may be a hard mask that can facilitate formation of the at least some of conductive structures in the memory layers 210.

The CMOS layer 220 includes a support structure 221, transistors 222 (individually referred to as “transistor 222”) with gates 223 (individually referred to as “gate 223”), interconnects 224, vias 225 (individually referred to as “via 225”), electrical insulators 226 and 227, and dielectric layers 228 (individually referred to as “dielectric layer 228”). In other embodiments, the CMOS layer 220 may include fewer, more, or other components.

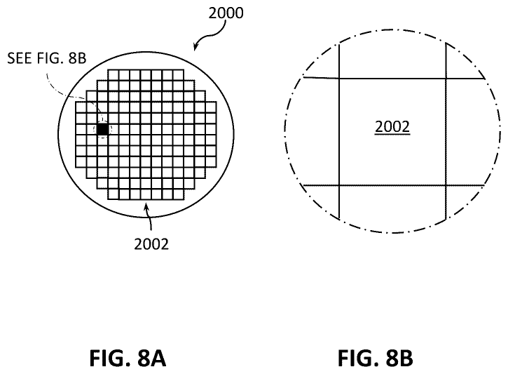

The support structure 221 may be any suitable structure, such as a substrate, a die, a wafer, or a chip, based on which transistors can be built. The support structure 221 may, e.g., be the wafer 2000 of FIG. 8A, discussed below, and may be, or be included in, a die, e.g., the singulated die 2002 of FIG. 8B, discussed below. In some embodiments, the support structure 221 may be a semiconductor substrate composed of semiconductor material systems including, for example, N-type or P-type materials systems, and, in some embodiments, the channel region, described herein, may be a part of the support structure 221. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors may be built on the support structure 221.

Although a few examples of materials from which the support structure 221 may be formed are described here, any material that may serve as a foundation upon which an IC may be built falls within the spirit and scope of the present disclosure. In various embodiments, the support structure 221 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 221 may provide material “support” in that, e.g., the IC devices/structures described herein are build based on the semiconductor materials of the support structure 221. However, in some embodiments, the support structure 221 may provide mechanical support.

Each transistor 222 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 222 includes a semiconductor structure that includes a channel region, a source region, and a drain region. The gate 223 of each transistor 222 may be over the channel region of the transistor 222. The gate 223 may include a gate electrode. The gate electrode can be coupled to a gate terminal that controls gate voltages applied on the transistor 222. The gate electrode may include one or more gate electrode materials, where the choice of the gate electrode materials may depend on whether the transistor 222 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer. The gate 223 may also include a gate insulator (not show in FIG. 2) that separates at least a portion of the channel region from the gate electrode so that the channel region is insulated from the gate electrode. In some embodiments, the gate insulator may wrap around at least a portion of the channel region. The gate insulator may also wrap around at least a portion of the source region 143 or the drain region. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The transistor 222 may also include a source electrode and drain electrode, which are not shown in FIG. 2. The source electrode or drain electrode may include one or more electrically conductive materials, such as metals. Examples of metals in the source electrode or drain electrode may include, but are not limited to, Ru, Cu, Co, Pd, Pt, Ni, and so on. The gate electrode, source electrode, or drain electrode may be connected to a via 225 and coupled to an interconnect 224. In some embodiments, the gate electrode, source electrode, or drain electrode may be coupled to power delivery or signal delivery components in the CMOS layer 220.

The interconnects 224 and vias 225 are conductive structures in the CMOS layer 220 and can facilitate delivery of power or signals to the memory cells. Each conductive structure may include one or more metals, such as tungsten (W), molybdenum (Mo), ruthenium (Ru), copper (Cu), other metals, or some combination thereof. An interconnect 213 may be connected to a via 215, which may be further connected to another via 215, the other interconnect 213, or an electrode of a transistor 222. The electrical insulators 226 and 227 may separate conductive structures in the CMOS layer 220 for insulating them from each other. The electrical insulator 226 or 227 may include a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc. The dielectric layers 228 may also be insulative. In some embodiments, a dielectric layer 228 may be a hard mask that can facilitate formation of the at least some of conductive structures in the CMOS layer 220.

The CMOS layer 220 further includes conductive structures 229. Each conductive structure 229 may be a via. The conductive structures 229 may facilitate connection between the CMOS layer 220 with the memory layer 210A. A conductive structure 229 may be coupled to a transistor 222, e.g., from the backside of the support structure 221. A conductive structure 229 may also be coupled to a via 225 in the CMOS layer 220, e.g., a via 225 that is coupled to a component in the memory layer 210A.

Each bonding layer 230 is between a memory layer 210 and the CMOS layer 220. The bonding layer 230A can bond the memory layer 210A with the CMOS layer 220. The bonding layer 230B can bond the memory layer 210B with the CMOS layer 220. Each bonding layer 230 includes a bonding material 231 and conductive structures 232. The boning material 231 may facilitate adhesion between the memory layer 210 and the CMOS layer 220. Examples of the bonding material 231 include the bonding materials described above in conjunction with FIG. 1A. The conductive structures 232 facilitate electrical connections between the memory layer 210 and the CMOS layer 220. The conductive structures 232 may be examples of the conductive structures 103 in FIG. 1A. Each conductive structure 232 penetrates through the boning material 231 and extends to the memory layer 210 and the CMOS layer 220. The conductive structure 232 may be connected to conductive structures (e.g., interconnect 213 or 214, via 215, etc.) in the memory layer 210. In some embodiments, each conductive structure 232 can couple a logic circuit in the CMOS layer 220 to components (e.g., conductive structures, transistors 211, capacitors 212, etc.) in the memory layer 210. In some embodiments, one or both bonding layers 230 may be optional. A memory layer 210 may be attached to the CMOS layer 220 without any bonding layer 230.

Even though FIG. 2 shows a single memory layer 210 at each side of the CMOS layer 220, the IC device 200 may include one or more additional memory layers 210 at either the frontside or backside of the CMOS layer 120. Also, for the purpose of simplicity and illustration, FIG. 2 may not show all the components in the IC device 200. For example, the IC device 200 may include one or more double poly interconnects, which may include polycrystalline silicon (or polysilicon). The double poly interconnects may be placed on top of the memory layer 210B. An example double poly interconnect may include two layers of polysilicon as conductive lines. The two layers of polysilicon may be separated by insulating layers.

FIG. 3 illustrates an IC device 300 including a stack of wafers, according to some embodiments of the disclosure. The IC device 300 may also be referred to as an IC device or IC assembly. The stack of wafers includes wafers 312A (individually referred to as “wafer 312A”), a wafer 314, and wafers 312B (individually referred to as “wafer 312B”). The wafers 312A may be at the frontside of the wafer 314, and the wafers 312B may be at the backside of the wafer 314. The wafers 312A and 312B may be collectively referred to as “wafers 312” or “wafer 312.” In other embodiments, the IC device 300 may include fewer, more, or different components. For instance, the IC device 300 may include a different number of wafers 312A at the frontside of the wafer 314 or a different number of wafers 312B at the backside of the wafer 314.

In some embodiments, each wafer 312 may be a memory wafer. The wafers 312 may include transistors forming memory cells to implement memory arrays of the IC device 300, while the wafer 314 may include transistors forming control logic configured to control operation of (e.g., to control input/output or read/write to) the memory arrays of the memory cells of the wafers 312. The wafers 312 may be referred to as “memory wafers.” The wafer 314 may be referred to as a “logic wafer,” “compute wafer,” or “compute logic wafer.” In some embodiments, the wafer 314 may include logic circuits used to control the wafers 312—like I/O, memory scheduler etc.

Each of the wafers 312 and 314 of the IC device 300 may be composed of one or more semiconductor materials and may include one or more dies having IC structures formed on a surface of the wafers 312 and 314. Even though FIG. 3 shows three wafers 312A on one side of the wafer 314 and three wafers 312B on the other side of the wafer 314, the IC device 300 may include a different number of wafers 314 on either side of the wafer 314.

As shown in FIG. 3, each wafer 312 includes a plurality of memory dies 320 (individually referred to as “memory die 320”). A memory die 320 may be referred to as a “memory chiplet.” An embodiment of a memory die 320 may be the memory die 320A or 320B in FIG. 3. The wafer 314 includes a plurality of logic dies 330 (individually referred to as “logic die 330”). A logic die 330 may be referred to as a “compute chiplet.” An embodiment of a logic die 330 may be the logic die 310 in FIG. 3. Each memory die 320 or logic die 310 may be a repeating unit of a semiconductor product that includes any suitable IC, e.g., an IC implementing memory, an IC implementing compute logic, etc. After the fabrication of the semiconductor product is complete, the wafers 312 and 314 may undergo a singulation process in which the memory dies 320 and the logic dies 330 are separated from one another to provide discrete “chips” of the semiconductor product.

Each memory die 320 includes a plurality of memory arrays, such as the memory arrays 115 in FIG. 1B. The memory dies 320 may be controlled by one or more logic circuits in the logic die 330. Also, the logic die 330 may include, or otherwise be associated with, power delivery components for delivering power to the memory devices 325. For instance, the logic die 330 may include one or more power interconnects, one or more power vias, etc. The logic die 330 may transmit signals to the memory devices 325 for reading data from the memory devices 325 or writing data into the memory devices 325. In some embodiments, the logic die 330 may include one or more processing units (e.g., central processing unit (CPU), graphics processing unit (GPU), etc.) that can generate data read or write signals, generate data to be written into memory cells in the memory layers 110, process data read from memory cells in the memory layers 110, and so on.

FIG. 4 is an electric circuit diagram of an example DRAM array 400, according to some embodiments of the present disclosure. The DRAM array 400 may be an example of the memory arrays 115 in FIG. 1B. As shown in FIG. 4, the DRAM array 400 is an array of memory cells 405-11, 405-12, 405-21, and 405-22 (collectively referred to as “memory cells 405” or “memory cell 405”), which are arranged in rows 410-1 and 410-2 (collectively referred to as “rows 410” or “row 410”) and columns 412-1 and 412-2 (collectively referred to as “columns 412” or “column 412”). Each memory cell 405 is illustrated within one of the dashed boxes in FIG. 4. Each memory cell 405 may be a DRAM cell. In other embodiments, the DRAM array 400 may include a different number of memory cells 405, a different number of rows 410, or a different number of columns 412.

The DRAM array 400 also includes three types of control lines: bit lines 440-1 and 440-2 (collectively referred to as “bit lines 440” or “bit line 440”), word lines 450-1 and 450-2 (collectively referred to as “word lines 450” or “word line 450”), and plate lines 460-1 and 460-2 (collectively referred to as “plate lines 460” or “plate line 460”), which control the memory cells 405. The memory cells 405 in the row 410-1 are coupled to the same bit line 440-1. The memory cells in the row 410-1 are coupled to the same bit line 440-2. The memory cells in the column 412-1 are coupled to the same word line 450-2 and the same plate line 460-2. The memory cells in the column 412-2 are coupled to the same word line 450-1 and the same plate line 460-1. As is conventionally used in context of memory, the terms “row” and “column” do not reflect the, respectively, horizontal and vertical orientation on a page of a drawing illustrating a memory array but, instead, reflect how individual memory cells are addressed. Namely, memory cells 405 sharing a single bit line 440 are said to be in the same row, while memory cells sharing a single word line 450 and a single plate line 460 are said to be on the same column. In other embodiments, the DRAM array 400 may include a different number of memory cells, bit lines, word lines, or plate lines. Furthermore, in other embodiments, the memory cells 405 may be arranged in arrays in a manner other than what is shown in FIG. 4, e.g., in any suitable manner of arranging memory cells into arrays as known in the art, all of which being within the scope of the present disclosure.

A memory cell 405 may store one bit of binary information. Each memory cell 405 is a 1T-1X memory cell. The memory cell 405 includes a memory element 420 and an access transistor 430. The memory element 420 is configured to store signals. The memory element 420 may have more than one state. The memory element 420 having two states may be referred to as a binary memory element. In other embodiments, the memory element 420 may have more than two states. In some embodiments, the memory element 420 is a capacitor that can store electrical voltage signals, and the memory cell 405 is a one-transistor one-capacitor (1T-1C) memory cell. In other embodiments, the memory element 420 may be, for example, a ferroelectric memory element, a magnetic storage element, a resistor, or another transistor, coupled to the access transistor 430. Also, the memory element 420 may store signals other than electrical voltage signals.

The access transistor 430 controls access to the memory cell 405. For instance, the access transistor 430 controls access to write information to the memory cell 405, access to read information from the memory cell 405, or both. The access transistor 430 has a gate terminal, a source terminal, and a drain terminal, indicated in the example of FIG. 4 as terminals G, S, and D, respectively. An embodiment of the access transistor 430 may be a vertical transistor, such as the vertical transistor 45 described above in conjunction in FIG. 1.

The access transistor 430 may be a nanowire-based or nanoribbon-based transistor (or, simply, a nanowire transistor or nanoribbon transistor). In a nanowire or nanoribbon transistor, a gate stack that may include a stack of one or more gate electrode metals and, optionally, a stack of one or more gate insulators may be provided around a portion of an elongated semiconductor structure called “nanowire or nanoribbon”, forming a gate on all sides of the nanowire or nanoribbon. The portion of the nanowire or nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanowire or nanoribbon, on either side of the gate stack, forming, respectively, a source and a drain of such a transistor. Wrap-around or all-around gate transistors, such as nanoribbon and nanowire transistors, may provide advantages compared to other transistors having a non-planar architecture, such as FinFETs, and transistors having planar architecture. In the following, the terms “terminal” and “electrode” may be used interchangeably. Furthermore, for S/D terminals, the terms “terminal” and “region” may be used interchangeably.

As shown in FIG. 4, the gate terminal of the access transistor 430 is coupled to a word line 450, one of the S/D terminals of the access transistor 430 is coupled to a bit line 440, and the other one of the S/D terminals of the access transistor 430 is coupled to a first terminal of the memory element 420, e.g., a first electrode of a capacitor. As also shown in FIG. 4, the other terminal of the memory element 420 may be coupled to a capacitor plate line 460. As is known in the art, word line, bit line, and plate line may be used together to read and program the memory element 420. In some embodiments (e.g., embodiments where the access transistor 430 is the vertical transistor 45), a portion of the bit line 440 may be a S/D region of the access transistor 430. Another S/D region of the access transistor 430 is coupled to the memory element 420. Also, a portion of the word line 450 may be a gate electrode of the access transistor 430. Such vertical transistors can improve the memory cell density of the DRAM array 400 so that more memory cells can be arranged in the available space of the DRAM array 400.

Each of the bit line 440, the word line 450, and the plate line 460, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In the embodiment of FIG. 4, a single plate line 460 is shared among multiple memory cells 405 of a given row. The plate lines 460 are shared among the same memory cells 405 among which the word line 450 are shared. Such an arrangement where the plate lines 460 are shared among the same memory cells among which the word lines 450 are shared may be described as an arrangement where the plate lines 460 are “parallel” to the word lines 450. Each memory cell 405 of the DRAM array 400 where the plate lines 460 are parallel to the word lines 450, e.g., as shown in FIG. 4, may then be addressed (e.g., to perform READ and WRITE operations) by using the word line 450 and the plate line 460 corresponding to the column 412 to which the memory cell 405 belongs and by using the bit line 440 corresponding to the row 410 to which the memory cell 405 belongs.

It should be noted that, just as the horizontal and vertical orientations on a page of an electrical circuit diagram illustrating a memory array does imply functional division of memory cells into rows and columns as used in common language, the orientation of various elements on a page of an electrical circuit diagram illustrating a memory array does not imply that the same orientation is used for the actual physical layout of a memory array. For example, in an IC device implementing the DRAM array 400 as shown in FIG. 2A, corresponding bit lines 440 and plate lines 460 (i.e., a pair of a bit line 440 and a plate line 460 coupled to a given column 412) do not have to physically extend in a direction parallel to one another (although they may), or the word lines 450 do not have to physically extend in a direction perpendicular to the bit lines 440 (although they may). In another example, in an IC device implementing the DRAM array 400 as shown in FIG. 4, corresponding word lines 450 and plate lines 460 (i.e., a pair of a word line 450 and a plate line 460 coupled to a given column 412) do not have to physically extend in a direction parallel to one another (although they may), or the word lines 450 do not have to physically extend in a direction perpendicular to the bit lines 440 (although they may).

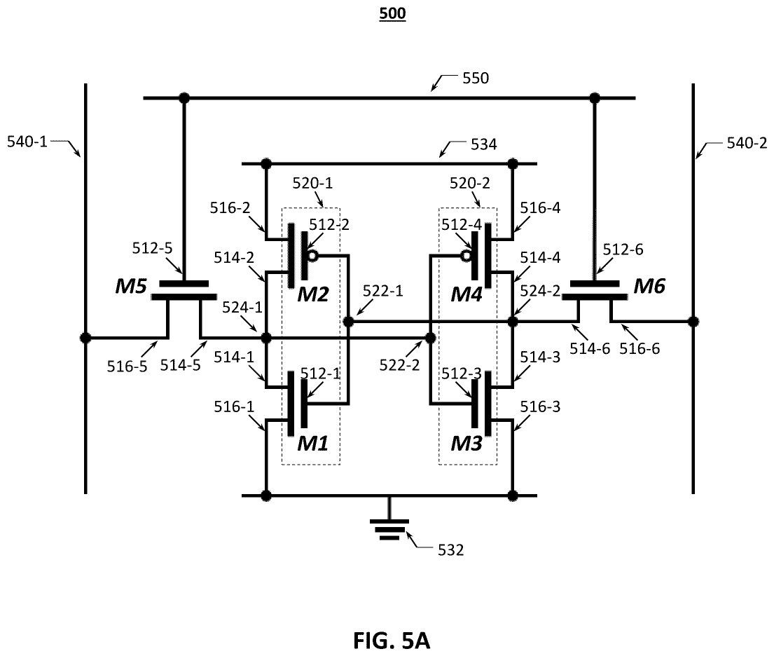

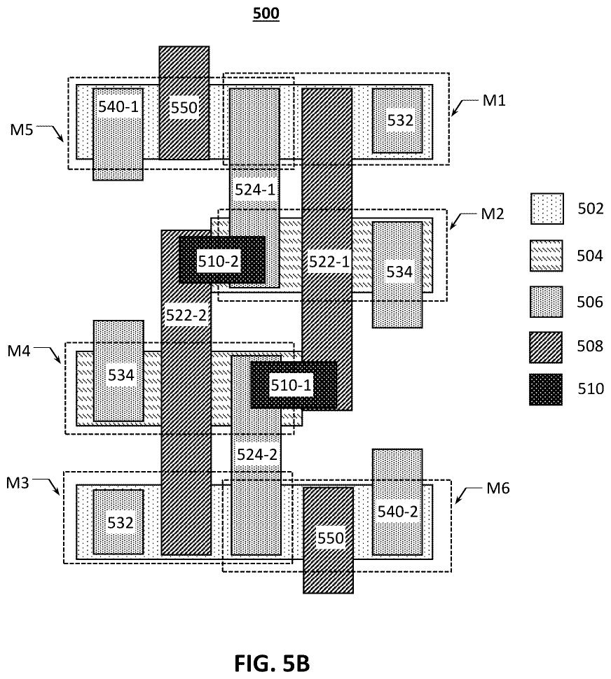

FIG. 5A is an electric circuit diagram of an example SRAM cell 500, according to some embodiments of the present disclosure. The SRAM cell 500 may be in a CMOS layer, such as the CMOS layer 120 in FIG. 1, the CMOS layer 220 in FIG. 2, the logic die 330 in FIG. 3, or the wafer 314 in FIG. 3. In some embodiments, the SRAM cell 500 may be used in an SRAM array. As shown in FIG. 5B, the SRAM cell 500 includes transistors M1-M4 for storing a bit value or a memory state (e.g., logic “1” or “0”) of the cell, and two access transistors, M5 and M6, for controlling access to the cell (e.g., access to write information to the cell or access to read information from the SRAM cell 500). The SRAM cell 500 is a 6-transistor (6T) memory cell. In other embodiments, the SRAM cell 500 may include a different number of transistors. Each of the transistors M1-M6 may have any transistor architecture (e.g., planar or non-planar, FinFET, nanoribbon/nanowire, etc.). For example, the transistors M1-M6 may have the transistor architecture shown in FIG. 4. An example of the transistors M1-M6 may be one of the transistors 222 in FIG. 2.

In the SRAM cell 500, each bit may be stored on four transistors (M1, M2, M3, M4) that form two cross-coupled inverters 520, each having an input 522 and an output 524. The first inverter 520-1 may be formed by an NMOS transistor M1 and a PMOS transistor M2, while the second inverter 520-2 may be formed by an NMOS transistor M3 and a PMOS transistor M4. As shown in FIG. 5B, the gate stack 512-1 of the transistor M1 may be coupled to the gate stack 512-2 of the transistor M2, and both of these gate stacks may be coupled to the input 522-1 of the first inverter 520-1. On the other hand, the first S/D region 514-1 of the transistor M1 may be coupled to the first S/D region 514-2 of the transistor M2, and both of these first S/D regions 514-1 and 514-2 may be coupled to the output 524-1 of the first inverter 520-1. Similarly, for the second inverter 320-2, the gate stack 512-3 of the transistor M3 may be coupled to the gate stack 512-4 of the transistor M4, and both of these gate stacks may be coupled to the input 522-2 of the second inverter 520-2, while the first S/D region 514-3 of the transistor M3 may be coupled to the first S/D region 514-4 of the transistor M4, and both of these first S/D regions 514-3 and 514-4 may be coupled to the output 524-2 of the second inverter 520-2. As also shown in FIG. 5B, when the transistors M1 and M3 are NMOS transistors and when the transistors M2 and M4 are PMOS transistors as illustrated in FIG. 5B, the second S/D regions 516-1 and 516-3 of the transistors M1 and M3 may be coupled to a ground voltage 532, while the second S/D regions 516-2 and 516-4 of the transistors M2 and M4 may be coupled to a supply voltage 534, e.g., VDD. In the embodiments of the SRAM cell 500 where the NMOS transistors shown in FIG. 5B are replaced with PMOS transistors and vice versa, the designation of the ground voltage 532 and the supply voltage 534 would be reversed as well, all of which embodiments being within the scope of the present disclosure.

The four transistors M1-M4 in such configuration form a stable storage cell for storing a bit value of 0 or 1. As further shown in FIG. 5B, two additional access transistors, M5 an M6, may serve to control the access to the storage cell of the transistors M1-M4 during read and write operations.

As shown in FIG. 5B, the first S/D region 514-5 of the access transistor M5 may be coupled to the output 524-1 of the first inverter 520-1. Phrased differently, the first S/D region 514-5 of the access transistor M5 may be coupled to each of the first S/D region 514-1 of the transistor M1 and the first S/D region 514-2 of the transistor M2. The second S/D region 516-5 of the access transistor M5 may be coupled to a first bit line 540-1. Thus, each of the first S/D region 514-1 of the transistor M1 and the first S/D region 514-2 of the transistor M2 may be coupled to the first bit line 540-1 (e.g., via the access transistor M5). The gate 512-5 of the access transistor M5 may be coupled to a word line 550.

As further shown in FIG. 5B, the first S/D region 514-6 of the access transistor M6 may be coupled to the output 524-2 of the second inverter 520-2. Phrased differently, the first S/D region 514-6 of the access transistor M6 may be coupled to each of the first S/D region 514-3 of the transistor M3 and the first S/D region 514-4 of the transistor M4. The second S/D region 516-6 of the access transistor M6 may be coupled to a second bit line 540-2. Thus, each of the first S/D region 514-3 of the transistor M3 and the first S/D region 514-4 of the transistor M4 may be coupled to the second bit line 540-2 (e.g., via the access transistor M6). The gate 512-6 of the access transistor M6 may be coupled to the word line 550. Thus, the gates 512-5 and 512-6 of both of the access transistors M5 and M6 may be coupled to a single, shared, word line, the word line 550.

As also shown in FIG. 5B, the input 522-1 of the first inverter 520-1 may be coupled to the first S/D region 514-6 of the access transistor M6, while the input 522-2 of the second inverter 520-2 may be coupled to the first S/D region 514-5 of the access transistor M5. In other words, each of the gate stack 512-1 of the transistor M1 and the gate stack 512-2 of the transistor M2 may be coupled to the first S/D region 514-6 of the access transistor M6, while each of the gate stack 512-3 of the transistor M3 and the gate stack 512-4 of the transistor M4 may be coupled to the first S/D region 514-5 of the access transistor M5. Phrased differently, each of the gate stack 512-1 of the transistor M1 and the gate stack 512-2 of the transistor M2 may be coupled to the second bit line 540-2 (e.g., via the access transistor M6), while each of the gate stack 512-3 of the transistor M3 and the gate stack 512-4 of the transistor M4 may be coupled to the first bit line 540-1 (e.g., via the access transistor M5).

The word line 550 and the first and second bit lines 540 may be used together to read and program (i.e., write to) the SRAM cell 500. In particular, access to the cell may be enabled by the word line 550 which controls the two access transistors M5 and M6 which, in turn, control whether the SRAM cell 500 should be connected to the bit lines 540-1 and 540-2. During operation of the SRAM cell 500, a signal on the first bit line 540-1 may be complementary to a signal on the second bit line 540-2. The two bit lines 540 may be used to transfer data for both read and write operations. In other embodiments of the SRAM cell 500, only a single bit line 540 may be used, instead of two bitlines 540-1 and 540-2, although having one signal bit line and one inverse, such as the two bit lines 540, may help improve noise margins.

During read accesses, the bit lines 540 are actively driven high and low by the inverters 520 in the SRAM cell 500. This may improve SRAM bandwidth compared to DRAM. The symmetric structure of the SRAM cell 500 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the word line 550 and the bit lines 540, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 5B provides a top-down plan view of an example implementation of the SRAM cell 900, according to some embodiments of the present disclosure. FIG. 5B illustrates how the six transistors M1-M6 shown in FIG. 5B may be implemented. Several elements from FIG. 5B are labelled in FIG. 5B. For example, the transistors M1-M6 are labelled in FIG. 5B, with the approximate boundaries of the individual transistors shown in FIG. 5B with dashed rectangles. Certain elements, e.g., the specific S/D regions 514 and 516 and the gate stacks 512, are not labelled in FIG. 5B in order to not clutter the drawings.

FIG. 5B illustrates that transistors M1 and M5 may be provided along a first region of an N-type semiconductor 502, transistors M2 and M4 may each be provided along a respective first and second region of a P-type semiconductor 504, and the transistors M4 and M6 may be provided along a second region of the N-type semiconductor 502. Each of the regions of the N-type semiconductor 502 and P-type semiconductor 504 may be formed in a support structure (e.g., a substrate) or over a support structure, e.g., as a fin or nanoribbon. The N-type semiconductor 502 is suitable for forming transistors of a first type, e.g., NMOS transistors, while the P-type semiconductor 504 is suitable for forming transistors of a second type, e.g., PMOS transistors, thus realizing NMOS transistors M1, M3, M5, and M6, and PMOS transistors M2 and M4, as shown in FIG. 5B.

In the plan view shown in FIG. 5B, S/D contacts 506, gate electrodes 508, and interconnects 510 are formed over the N-type and P-type semiconductors 502 and 504, e.g., as layers processed over the N-type and P-type semiconductors 502 and 504. While not specifically shown in FIG. 5B, S/D regions may be formed under the S/D contacts 506, and gate dielectrics may be formed under the gate electrodes 508. Any of the materials and processes described with respect to FIG. 4 may be used to form the transistors shown in FIG. 5B.

More specifically, a shared gate stack may be used to realize the gate stack 512-1 of the transistor M1 coupled to the gate stack 512-2 of the transistor M2. The shared gate stack is labelled 522-1 in FIG. 5B, representing a node that is the input 522-1 of the first inverter 520-1 of the SRAM cell 500. Similarly, a shared gate stack may be used to realize the gate stack 212-3 of the transistor M3 coupled to the gate stack 212-4 of the transistor M4 3. The shared gate stack is labelled 522-2 in FIG. 5B, representing a node that is the input 522-2 of the second inverter 520-2 of the SRAM cell 500.

As also shown in FIG. 5B, a first shared S/D contact may be used to realize the first S/D region 514-1 of the transistor M1 coupled to the first S/D region 514-2 of the transistor M2. The first shared S/D contact is labelled 524-1 in FIG. 5B, representing a node that is the output 524-1 of the first inverter 520-1 of the SRAM cell 500. Similarly, a second shared S/D contact may be used to realize the first S/D region 514-3 of the transistor M3 coupled to the first S/D region 514-4 of the transistor M4. The first shared S/D contact is labelled 524-2 in FIG. 5B, representing a node that is the output 524-2 of the second inverter 520-2 of the SRAM cell 500.

A first interconnect 510-1, shown in FIG. 5B, may then be used to couple the shared gate stack 522-1 of the first inverter 520-1 to the shared S/D contact 524-2 of the second inverter 520-2, thus realizing the coupling of the input 522-1 of the first inverter 520-1 to the output 524-2 of the second inverter 520-2, shown in FIG. 5B. Similarly, a second interconnect 510-2, shown in FIG. 5B, may then be used to couple the shared gate stack 522-2 of the second inverter 520-2 to the shared interconnect 524-1 of the first inverter 520-1, thus realizing the coupling of the input 522-2 of the second inverter 520-2 to the output 524-1 of the first inverter 520-1, shown in FIG. 5B.

FIG. 5B further illustrates that, in a given SRAM cell 500, the first S/D region 514-5 of the transistor M5 may be shared with (e.g., be the same as) the first S/D region 514-1 of the transistor M1 (since both of these transistors are implemented in a single region of the N-type semiconductor 502). In addition, the first S/D region 514-3 of the transistor M3 may be shared with (e.g., be the same as) the first S/D region 514-6 of the transistor M6 (since both of these transistors are implemented in a single region of the N-type semiconductor 502).

Both of the second S/D region 516-1 of the transistor M1 and the second S/D region 516-3 of the transistor M3 may be coupled to the ground voltage 532, as was described with reference to FIG. 5B. Both of the second S/D region 516-2 of the transistor M2 and the second S/D region 516-4 of the transistor M4 may be coupled to the supply voltage 534, as was described with reference to FIG. 5B.

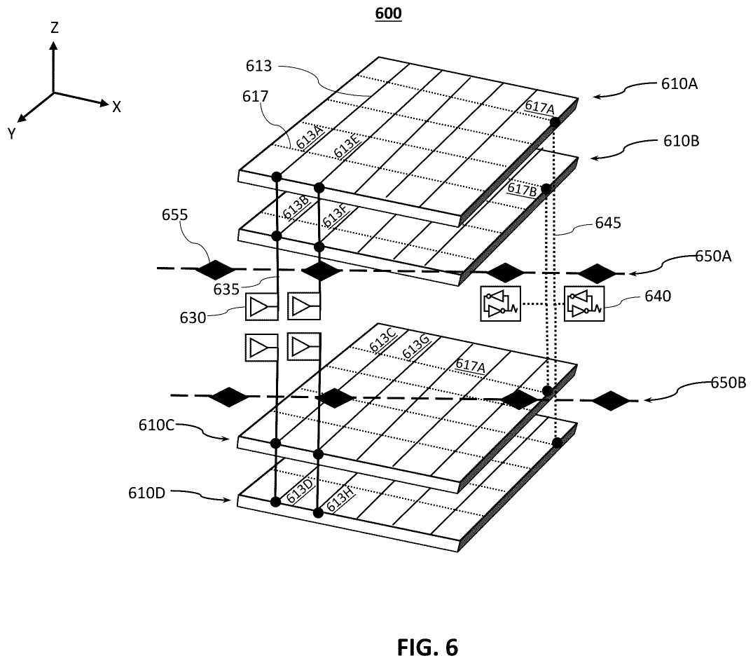

FIG. 6 illustrates an IIC device 600 with memory layers 610A-610D sharing word line drivers 630 and sense amplifiers 640 in a CMOS layer that is boned to the memory layers 610A-610D through bonding layers 630A and 630B, according to some embodiments of the present disclosure. The IC device 600 may be an example of the IC device 100 of FIG. 1 or the IC device 200 of FIG. 2. In the embodiments of FIG. 6, the CMOS layer is between the memory layers 610B and 610C, so that the memory layers 610A and 610B are at the frontside of the CMOS layer versus the memory layers 610C and 610D are at the backside of the CMOS layer. The four memory layers 610A-210D may be referred to as “memory layers 610” or “memory layer 610.” In other embodiments, the IC device 600 may include a different number of memory layers at either side of the CMOS layer. For the purpose of illustration, the CMOS layer is not shown in FIG. 6. Also, the IC device 600 may include other components that are not shown in FIG. 6, such as bonding layers, vias, and so on.

The CMOS layer provides power and signals to the memory layers 610. The CMOS layer may also receive signals (e.g., data stored in the memory layers 610) from the memory layers 610. The CMOS layer may be an example of the CMOS layer 120 in FIG. 1. In the embodiments of FIG. 6, the CMOS layer includes four word line drivers 630 (individually referred to as “word line driver 630”) and a sense amplifier 640. Even though not shown in FIG. 6, the CMOS layer may include other components, such as additional word line driver 630, additional sense amplifier 640, row decoders, column decoders, SRAM arrays, and so on. The word line drivers 630 may be separate from each other. In some embodiments, the word line drivers 630 are separated from each other by one or more electrical insulators.

Each memory layer 610 includes word lines 613 (individually referred to as “word line 613”) and bit lines 617 (individually referred to as “word line 613”). Each memory layer 610 may also include memory cells coupled to the word lines 613 and bit lines 617. The word lines 613 may be examples of the word lines 113 in FIG. 1, the bit lines 617 may be examples of the bit lines 117 in FIG. 1. The memory layers 610 may be examples of the memory layers 110 in FIG. 1. In some embodiments, the word lines 613 are coupled to the word line drivers 630 in the CMOS layer, and the bit lines 617 are coupled to the sense amplifiers 640 in the CMOS layer.

For the purpose of simplicity and illustration, FIG. 6 shows connections between representative word lines 613A-613H and the word line drivers 630 and connections between representative bit lines 617A-617D and sense amplifiers 640. The IC device 600 may include other connections between word lines 613 and word line drivers 630 or other connections between bit lines 617 and sense amplifiers 640. As shown in FIG. 6, the word line 613A and bit line 617A are in the memory layer 610A; the word line 613B and bit line 617B are in the memory layer 610B; the word line 613C and bit line 617C are in the memory layer 610C; and the word line 613D and bit line 617D are in the memory layer 610D.

The IC device 600 has a “front-back word line drivers” plus “near-far” sense amplifiers arrangement. As shown in FIG. 6, the word lines 613A and 613D (i.e., far word lines) are coupled to a word line driver 630 (i.e., a far word line driver). The word lines 613E and 613F (i.e., far word lines) are coupled to another word line driver 630 (i.e., another far word line driver). The word lines 613B and 613D (i.e., a near word lines) are coupled to another word line driver 630 (i.e., near word line driver). The word lines 613G and 613H (i.e., near word lines) are coupled to another word line driver 630 (i.e., another near word line driver). The word lines 613A-613H are coupled to the word line drivers 630 through conductive structures 635. The bit lines 617A and 617B (i.e., front bit lines) are coupled to a sense amplifier 640 (i.e., a front sense amplifier). The bit lines 617C and 617D (i.e., back bit lines) are coupled to a sense amplifier 640 (i.e., a back sense amplifier).

A conductive structure 635 or 645 may extend in a direction perpendicular to the memory layers 610. Each conductive structure 635 or 645 may include one or more vias, including TSVs. Memory cells in different memory layers 610 may have different memory addresses, based on which the memory cells may be located, selected, or accessed.

The bonding layer 650A is between the memory layer 610B and the CMOS layer. The bonding layer 650B is between the memory layer 610C and the CMOS layer. The bonding layers 650A and 650B may be examples of the bonding layers 130 in FIG. 1. Each of the bonding layers 650A and 650B includes conductive structures 655 (individually referred to as “conductive structure 655”). The conductive structures 655 may be examples of the conductive structures 103.

FIG. 7 illustrates another IC device 700 with memory layers 710A-510D sharing word line drivers 730 and sense amplifiers 740 in a CMOS layer that is boned to the memory layers 710A-510D through bonding layers 750A and 750B, according to some embodiments of the present disclosure. The IC device 700 may be an example of the IC device 100 of FIG. 1 or the IC device 200 of FIG. 2. In the embodiments of FIG. 7, the CMOS layer is between the memory layers 710B and 710C, so that the memory layers 710A and 710B are at the frontside of the CMOS layer versus the memory layers 710C and 710D are at the backside of the CMOS layer. The four memory layers 710A-210D may be referred to as “memory layers 710” or “memory layer 710.” In other embodiments, the IC device 700 may include a different number of memory layers at either side of the CMOS layer. For the purpose of illustration, the CMOS layer is not shown in FIG. 7. Also, the IC device 700 may include other components that are not shown in FIG. 7, such as bonding layers, vias, and so on.

The CMOS layer provides power and signals to the memory layers 710. The CMOS layer may also receive signals (e.g., data stored in the memory layers 710) from the memory layers 710. The CMOS layer may be an example of the CMOS layer 120 in FIG. 1. In the embodiments of FIG. 7, the CMOS layer includes four word line drivers 730 (individually referred to as “word line driver 730”) and a sense amplifier 740. Even though not shown in FIG. 7, the CMOS layer may include other components, such as additional word line driver 730, additional sense amplifier 740, row decoders, column decoders, SRAM arrays, and so on. The word line drivers 730 may be separate from each other. In some embodiments, the word line drivers 730 are separated from each other by one or more electrical insulators.

Each memory layer 710 includes word lines 713 (individually referred to as “word line 713”) and bit lines 717 (individually referred to as “word line 713”). Each memory layer 710 may also include memory cells coupled to the word lines 713 and bit lines 717. The word lines 713 may be examples of the word lines 113 in FIG. 1, the bit lines 717 may be examples of the bit lines 117 in FIG. 1. The memory layers 710 may be examples of the memory layers 110 in FIG. 1. In some embodiments, the word lines 713 are coupled to the word line drivers 730 in the CMOS layer, and the bit lines 717 are coupled to the sense amplifiers 740 in the CMOS layer.

For the purpose of simplicity and illustration, FIG. 7 shows connections between representative word lines 713A-513D and the word line drivers 730 and connections between representative bit lines 717A-517D and sense amplifier 740. The IC device 700 may include other connections between word lines 713 and word line drivers 730 or other connections between bit lines 717 and sense amplifier 740. As shown in FIG. 7, the word line 713A and bit line 717A are in the memory layer 710A; the word line 713B and bit line 717B are in the memory layer 710B; the word line 713C and bit line 717C are in the memory layer 710C; and the word line 713D and bit line 717D are in the memory layer 710D.

The IC device 700 has a “near-far” word line drivers plus “front-back” sense amplifiers arrangement. As shown in FIG. 7, the word lines 713A and 713D (i.e., far word lines) are coupled to a word line driver 730 (i.e., a far word line driver). The word lines 713B and 713D (i.e., near word lines) are coupled to another word line driver 730 (i.e., a near word line driver). The word lines 713A-513D are coupled to the word line drivers 730 through conductive structures 735. The bit lines 717A and 717B (i.e., front bit lines) are coupled to a sense amplifier 740 (i.e., a front sense amplifier). The bit lines 717C and 717D (i.e., a back bit lines) are coupled to a sense amplifier 740 (i.e., back sense amplifier). A conductive structure 735 or 745 may extend in a direction perpendicular to the memory layers 710. Each conductive structure 735 or 745 may include one or more vias, including TSVs. Memory cells in different memory layers 710 may have different memory addresses, based on which the memory cells may be located, selected, or accessed.

The bonding layer 750A is between the memory layer 710B and the CMOS layer. The bonding layer 750B is between the memory layer 710C and the CMOS layer. The bonding layers 750A and 750B may be examples of the bonding layers 130 in FIG. 1. Each of the bonding layers 750A and 750B includes conductive structures 755 (individually referred to as “conductive structure 755”). The conductive structures 755 may be examples of the conductive structures 103.

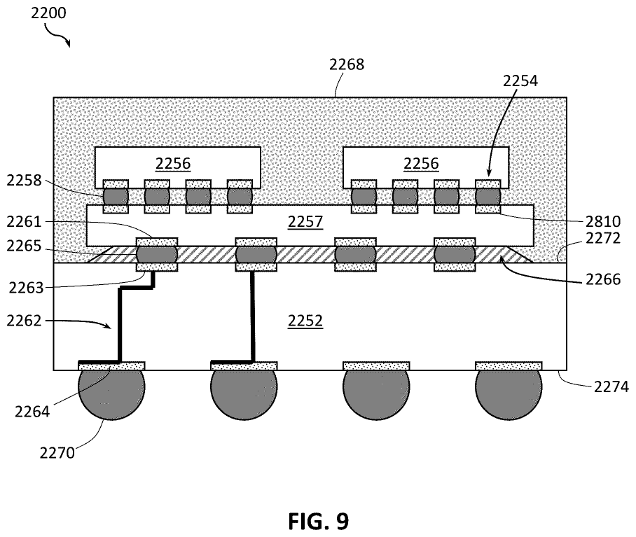

FIGS. 8A and 8B are top views of a wafer 2000 and dies 2002 that can facilitate memory layers at opposing sides of a CMOS layer, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 9. The wafer 2000 may be composed of semiconductor material and may include one or more dies 2002 having IC devices formed on a surface of the wafer 2000. Each of the dies 2002 may be a repeating unit of a semiconductor product that includes any suitable IC. After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include memory layers at opposing sides of a CMOS layer as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 9 is a side, cross-sectional view of an example IC package 2200 that may include memory layers at opposing sides of a CMOS layer, according to some embodiments of the disclosure. In some embodiments, the IC package 2200 may be a system-in-package (SiP).

As shown in FIG. 9, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 9 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 9 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

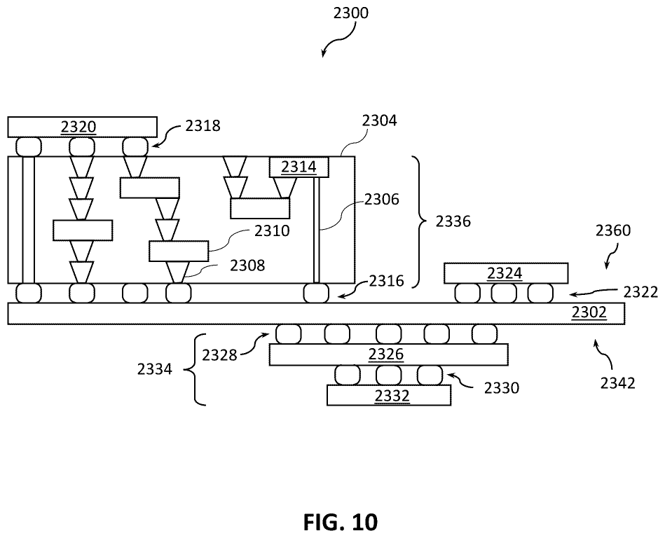

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 9 are solder balls (e.g., for a ball grid array (BGA) arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 10.

The dies 2256 may take the form of any of the embodiments of the die 2002 discussed herein and may include any of the embodiments of an IC device with memory layers at opposing sides of a CMOS layer. In embodiments in which the IC package 2200 includes multiple dies 2256, the IC package 2200 may be referred to as a multi-chip package. Importantly, even in such embodiments of an MCP implementation of the IC package 2200, one or more IC devices with memory layers at opposing sides of a CMOS layer may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc.

The IC package 2200 illustrated in FIG. 9 may be a flip chip package, although other package architectures may be used. For example, the IC package 2200 may be a BGA package, such as an embedded wafer-level BGA package. In another example, the IC package 2200 may be a wafer-level chip scale package or a panel fan-out package. Although two dies 2256 are illustrated in the IC package 2200 of FIG. 9, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 10 is a cross-sectional side view of an IC device assembly 2300 that may include components having memory layers at opposing sides of a CMOS layer, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include memory layers at opposing sides of a CMOS layer in accordance with any of the embodiments disclosed herein; e.g., any of the IC packages discussed below with reference to the IC device assembly 2300 may take the form of any of the embodiments of the IC package 2200 discussed above with reference to FIG. 9 (e.g., may include memory layers at opposing sides of a CMOS layer).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 10 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 8B), an IC device (e.g., the IC device 100, 200, 300, 600, or 700), or any other suitable component. In particular, the IC package 2320 may include memory layers at opposing sides of a CMOS layer as described herein. Although a single IC package 2320 is shown in FIG. 10, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 10, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further radio frequency (RF) devices, power amplifiers, power management devices, antennas, arrays, sensors, and microelectromechanical systems (MEMS) devices may also be formed on the interposer 2304. In some embodiments, memory layers at opposing sides of a CMOS layer as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 10 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

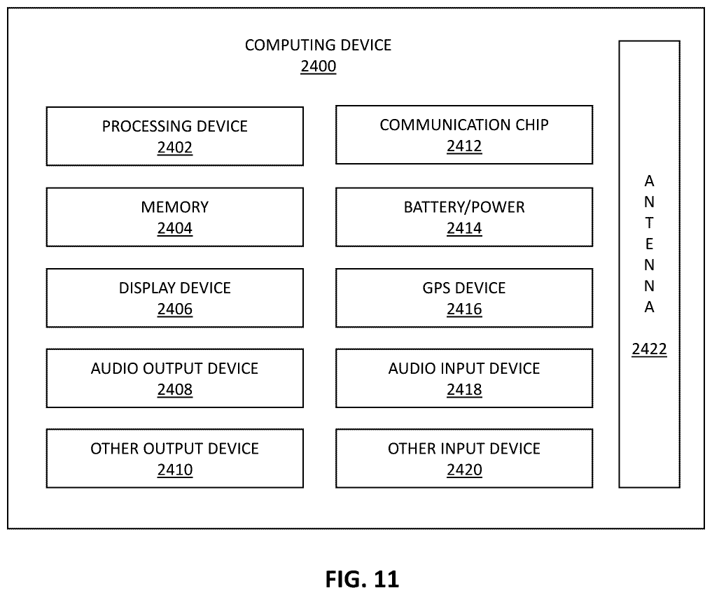

FIG. 11 is a block diagram of an example computing device 2400 that may include one or more components with memory layers at opposing sides of a CMOS layer, according to some embodiments of the disclosure. For example, any suitable ones of the components of the computing device 2400 may include one or more dies (e.g., the die 2002 of FIG. 8B) that can facilitate memory layers at opposing sides of a CMOS layer, according to some embodiments of the disclosure. Any of the components of the computing device 2400 may include an IC device (e.g., the IC device 100, 200, 300, 600, or 700) and/or an IC package (e.g., the IC package 2200 of FIG. 9). Any of the components of the computing device 2400 may include an IC device assembly (e.g., the IC device assembly 2300 of FIG. 10).

A number of components are illustrated in FIG. 11 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 11, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), CPUs, GPUs, cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an integrated circuit (IC) device, including a logic layer including a logic circuit; a first memory layer at a first side of the logic layer, the first memory layer including a first memory cell; a second memory layer at a second side of the logic layer, the second memory layer including a second memory cell, the second side opposing the first side; and a bonding layer between the logic layer and the first memory layer, the bonding layer including a conductive structure that is coupled to the logic circuit and a first memory cell.

Example 2 provides the IC device according to example 1, in which the bonding layer is a first bonding layer, the conductive structure is a first conductive structure, and the IC device further includes a second bonding layer between the logic layer and the second memory layer, the second bonding layer including a second conductive structure that is coupled to the logic circuit and a second memory cell.

Example 3 provides the IC device according to example 1 or 2, in which: the logic circuit includes a transistor, the logic layer further includes an additional conductive structure, and the additional conductive structure is at the first side of the transistor and is coupled to the conductive structure.

Example 4 provides the IC device according to any one of examples 1-3, in which the logic layer further includes a third memory cell, and the third memory cell is of a different type from the first memory cell or the second memory cell.

Example 5 provides the IC device according to example 4, in which the first memory cell or the second memory cell is a DRAM cell, and the third memory cell is a SRAM cell.

Example 6 provides the IC device according to any one of examples 1-5, further including one or more additional memory layers at the first side or the second side of the logic layer, in which the one or more additional layers are over the first memory layer or the second memory layer, and the one or more additional layers includes additional memory cells coupled to the logic circuit.

Example 7 provides the IC device according to any one of examples 1-6, in which the bonding layer further includes an additional conductive structure, and a distance from a center of the conductive structure to a center of the additional conductive structure is in a range from approximately 50 nanometers to approximately 15 micrometers.

Example 8 provides the IC device according to example 7, in which the first memory cell or the second memory cell includes a transistor and a capacitor, the capacitor is coupled to an electrode of the transistor, the electrode is over a source region or drain region of the transistor.

Example 9 provides the IC device according to example 8, in which: the first memory cell further includes a bit line, and the bit line is coupled to the logic circuit and to an additional electrode of the transistor, and the additional electrode is over a channel region of the transistor.

Example 10 provides the IC device according to any one of examples 1-9, in which the logic circuit includes a P-type metal-oxide-semiconductor field-effect transistor and a N-type metal-oxide-semiconductor field-effect transistor.

Example 11 provides an integrated circuit (IC) device, including an array of first transistors in a first layer, an individual first transistor coupled to a first bit line or a first word line in the first layer; an array of second transistors in a second layer, an individual second transistor coupled to a second bit line or a second word line in the second layer; and a group of third transistors in a third layer, an individual third transistor is a metal-oxide-semiconductor field-effect transistor, in which the third layer is between the first layer and the second layer, and the third transistor is coupled to the first bit line, the first word line, the second bit line, or the second word line.

Example 12 provides the IC device according to example 11, further including a fourth layer between the first layer and the third layer, the fourth layer including conductive structures coupled to the array of first transistors and to the group of third transistors.

Example 13 provides the IC device according to example 12, further including a fifth layer between the second layer and the third layer, the fourth layer including conductive structures coupled to the array of second transistors and to the group of third transistors.

Example 14 provides the IC device according to example 12 or 13, in which a center-to-center distance of the conductive structures is in a range from approximately 50 nanometers to approximately 15 micrometers.

Example 15 provides the IC device according to any one of examples 11-14, in which: the third transistor is connected to a conductive structure in the third layer, the conductive structure is between the third transistor and the first layer, and the conductive structure is coupled to the array of first transistors.

Example 16 provides a method of forming an integrated circuit (IC) device, the method including forming an array of first transistors in a first layer; forming a first bit line and a first word line in the first layer; forming an array of second transistors in a second layer; forming a second bit line and a second word line in the first layer; forming metal-oxide-semiconductor field-effect transistors in a third layer; after the metal-oxide-semiconductor field-effect transistors are formed, forming the IC device by bonding the first layer, the second layer, and the third layer, in which an individual metal-oxide-semiconductor field-effect transistor is coupled to the first bit line, the first word line, the second bit line, or the second word line, and the second layer is between the first layer and the third layer in the IC device.

Example 17 provides the method according to example 16, in which bonding the first layer, the second layer, and the third layer includes forming a fourth layer between the first layer and the third layer, the fourth layer including conductive structures coupled to the array of first transistors and to the metal-oxide-semiconductor field-effect transistors.

Example 18 provides the method according to example 17, in which bonding the first layer, the second layer, and the third layer further includes forming a fifth layer between the second layer and the third layer, the fourth layer including conductive structures coupled to the array of second transistors and to the metal-oxide-semiconductor field-effect transistors.

Example 19 provides the method according to example 17 or 18, in which a center-to-center distance of the conductive structures is in a range from approximately 50 nanometers to approximately 15 micrometers.

Example 20 provides the method according to any one of examples 16-19, further including forming a conductive structure between the metal-oxide-semiconductor field-effect transistor and the first layer, in which the conductive structure is connected to the metal-oxide-semiconductor field-effect transistor and is coupled to the array of first transistors.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a logic layer comprising a logic circuit;
a first memory layer at a first side of the logic layer, the first memory layer comprising a first memory cell;
a second memory layer at a second side of the logic layer, the second memory layer comprising a second memory cell, the second side opposing the first side; and
a bonding layer between the logic layer and the first memory layer, the bonding layer comprising a conductive structure that is coupled to the logic circuit and a first memory cell.

2. The IC device according to claim 1, wherein the bonding layer is a first bonding layer, the conductive structure is a first conductive structure, and the IC device further comprises:
a second bonding layer between the logic layer and the second memory layer, the second bonding layer comprising a second conductive structure that is coupled to the logic circuit and a second memory cell.

3. The IC device according to claim 1, wherein:
the logic circuit comprises a transistor,
the logic layer further comprises an additional conductive structure, and
the additional conductive structure is at the first side of the transistor and is coupled to the conductive structure.

4. The IC device according to claim 1, wherein the logic layer further comprises a third memory cell, and the third memory cell is of a different type from the first memory cell or the second memory cell.

5. The IC device according to claim 4, wherein the first memory cell or the second memory cell is a DRAM cell, and the third memory cell is a SRAM cell.

6. The IC device according to claim 1, further comprising:
one or more additional memory layers at the first side or the second side of the logic layer, wherein the one or more additional layers are over the first memory layer or the second memory layer, and the one or more additional layers comprises additional memory cells coupled to the logic circuit.

7. The IC device according to claim 1, wherein the bonding layer further comprises an additional conductive structure, and a distance from a center of the conductive structure to a center of the additional conductive structure is in a range from approximately 50 nanometers to approximately 15 micrometers.

8. The IC device according to claim 7, wherein the first memory cell or the second memory cell comprises a transistor and a capacitor, the capacitor is coupled to an electrode of the transistor, the electrode is over a source region or drain region of the transistor.

9. The IC device according to claim 8, wherein:
the first memory cell further comprises a bit line, and
the bit line is coupled to the logic circuit and to an additional electrode of the transistor, and
the additional electrode is over a channel region of the transistor.

10. The IC device according to claim 1, wherein the logic circuit comprises a P-type metal-oxide-semiconductor field-effect transistor and a N-type metal-oxide-semiconductor field-effect transistor.

11. An integrated circuit (IC) device, comprising:
an array of first transistors in a first layer, an individual first transistor coupled to a first bit line or a first word line in the first layer;
an array of second transistors in a second layer, an individual second transistor coupled to a second bit line or a second word line in the second layer; and
a group of third transistors in a third layer, an individual third transistor is a metal-oxide-semiconductor field-effect transistor,
wherein the third layer is between the first layer and the second layer, and the third transistor is coupled to the first bit line, the first word line, the second bit line, or the second word line.

12. The IC device according to claim 11, further comprising:
a fourth layer between the first layer and the third layer, the fourth layer comprising conductive structures coupled to the array of first transistors and to the group of third transistors.

13. The IC device according to claim 12, further comprising:
a fifth layer between the second layer and the third layer, the fourth layer comprising conductive structures coupled to the array of second transistors and to the group of third transistors.

14. The IC device according to claim 12, wherein a center-to-center distance of the conductive structures is in a range from approximately 50 nanometers to approximately 15 micrometers.

15. The IC device according to claim 11, wherein:
the third transistor is connected to a conductive structure in the third layer,
the conductive structure is between the third transistor and the first layer, and
the conductive structure is coupled to the array of first transistors.

16. A method of forming an integrated circuit (IC) device, the method comprising:
forming an array of first transistors in a first layer;
forming a first bit line and a first word line in the first layer;
forming an array of second transistors in a second layer;
forming a second bit line and a second word line in the first layer;
forming metal-oxide-semiconductor field-effect transistors in a third layer; and
after the metal-oxide-semiconductor field-effect transistors are formed, forming the IC device by bonding the first layer, the second layer, and the third layer,
wherein an individual metal-oxide-semiconductor field-effect transistor is coupled to the first bit line, the first word line, the second bit line, or the second word line, and the second layer is between the first layer and the third layer in the IC device.

17. The method according to claim 16, wherein bonding the first layer, the second layer, and the third layer comprises:
forming a fourth layer between the first layer and the third layer, the fourth layer comprising conductive structures coupled to the array of first transistors and to the metal-oxide-semiconductor field-effect transistors.

18. The method according to claim 17, wherein bonding the first layer, the second layer, and the third layer further comprises:
forming a fifth layer between the second layer and the third layer, the fourth layer comprising conductive structures coupled to the array of second transistors and to the metal-oxide-semiconductor field-effect transistors.

19. The method according to claim 17, wherein a center-to-center distance of the conductive structures is in a range from approximately 50 nanometers to approximately 15 micrometers.

20. The method according to claim 16, further comprising:
forming a conductive structure between the metal-oxide-semiconductor field-effect transistor and the first layer,
wherein the conductive structure is connected to the metal-oxide-semiconductor field-effect transistor and is coupled to the array of first transistors.
